(19) United States
(12) Patent Application Publication
(10) Pub. No.: US 2010/0304512 A1
(43) Pub. Date: Dec. 2, 2010

(54) System for Diagnosis and Treatment of Photovoltaic and Other Semiconductor Devices

(75) Inventors: Victor G. Karpov, Toledo, OH (US); Diana Shvydka, Toledo, OH (US)

Correspondence Address: MACMILLAN SOBANSKI & TODD, LLC, ONE MARITIME PLAZA FIFTH FLOOR, 720 WATER STREET, TOLEDO, OH, 43604-1619, US

(73) Assignee: UNIVERSITY OF TOLEDO, Toledo, OH (US)

(21) Appl. No.: 12/744,762

(22) PCT Filed: Nov. 26, 2008
(86) PCT No.: PCT/US08/84813

§ 371 Date: Jun. 29, 2010

Related U.S. Application Data
(60) Provisional application No. 61/004,862, filed on Nov. 30, 2007.

(51) Int. Cl. H01L 21/66; G01R 31/26

(52) U.S. Cl. 438/18; 324/761.01; 257/E21.531

(57) ABSTRACT

A diagnostic and self-healing treatment system for a semiconductor device, the system provides: i) a shunt busting/blocking treatment, ii) self-healing treatment, and iii) an in-situ non-contact diagnostic determination.

### CROSS-REFERENCE TO RELATED APPLICATIONS

This application claims the benefit of U.S. Provisional Application No. 61/004,862 filed Nov. 30, 2007, the disclosure of which is incorporated herein by reference.

### STATEMENT REGARDING SPONSORED RESEARCH

This invention was made with government support under the Department of Energy through National Renewable Energy Laboratory Grant Number NDJ-1-30630-02. The government has certain rights in this invention.

### TECHNICAL FIELD

The present invention concerns semiconductor devices and a system of manufacturing semiconductor devices. More particularly, this invention relates to a system of manufacturing a semiconductor junction structure that includes selectively creating an electrically modified layer over areas of aberrant electric potential that deviate from the average electric potential in a semiconductor or electrode layer of a semiconductor device.

### BACKGROUND OF THE INVENTION

Thin film semiconductor structures have recently found increasing popularity in industries requiring large active area semiconductor devices, such as the terrestrial photovoltaic, light emitting panel, and liquid crystal display driver fields. All of the above fields may incorporate devices having a photovoltaic cell type structure that generates voltage in response to absorbed light energy.

A typical photovoltaic (PV) cell includes a substrate layer for mounting the cell and two electric contacts or conductors for collecting and passing current to an external electrical circuit. The cell also includes an individual multi-layer semiconductor cell or several semiconductor cells connected in series. The cells operate by having readily excitable electrons that can be energized by solar energy to higher energy levels, thereby creating positively charged holes and negatively charged electrons at the interface of various semiconductor layers. The creation of these positive and negative charge carriers applies a net voltage across a base electrode layer and a top electrode layer positioned on either side of the semiconductor layer of the PV cell, which can force a current of electricity when the device is connected to a proper electric circuit.

The application of semiconductor devices in industries such as those mentioned above has created a need for semiconductor devices having active area requirements extending up to approximately one square meter. Due to these size requirements, the use of polycrystalline or amorphous thin film semiconductor material layers has become increasingly popular in semiconductor device design, as opposed to known crystalline semiconductor structures, which are both limited in size and expensive to manufacture.

However, inherent in such polycrystalline or amorphous thin film layer semiconductor device configurations is the presence of various structural nonuniformities. Where a PV cell structure is used, these structural nonuniformities can cause lateral fluctuations in the electric potential at the surfaces of the various layers of the PV device (areas of low electric resistance are often referred to as shunts) as well as cause forward current leakage paths (often referred to as weak diodes).

The structural nonuniformities can result from either defects within various semiconductor layers of the device or from morphological irregularities in the deposition surface of the substrate material. These defects lead to an overall decrease in the efficiency of the semiconductor device.

In order to minimize the negative impact such structural nonuniformities have on the performance of a PV device, it is desired to treat or minimize the nonuniformities that effectively disable the semiconductor defect regions by destroying or isolating the corresponding defect region present in the layers of the PV device.

There is a continuing need for improved systems for minimizing the effects of structural nonuniformities in PV cells utilizing thin-film semiconductor devices.

There is also a continuing need for a more efficient, less expensive, and longer lasting thin-film semiconductor device.

Thus, it would be advantageous to develop an improved system for treating structural nonuniformities in semiconductor devices that modifies the electric potential of localized defect areas within the semiconductor device to create a more uniform distribution of the electric potential generated by the semiconductor device.

### SUMMARY OF THE INVENTION

The above objects, as well as other objects not specifically enumerated, are achieved by a system for treating structural nonuniformities in semiconductor devices that modifies the electric potential of localized defect areas within the semiconductor device to create a more uniform distribution of the electric potential generated by the semiconductor device.

In a broad aspect, there is provided herein a Self-Healing Universal Non-uniformity Treatment (SHUNT) system that is useful as a self-healing electrolyte treatment to photovoltaic or other semiconductor devices using external forward bias blocking low voltage regions.

In another broad aspect, there is provided herein a self-healing universal non-uniformity treatment (SHUNT) system comprising combining a self-healing treatment with a shunt busting or blocking treatment and an in-situ nonuniformity diagnostic function.

In a first broad aspect, there is provided herein a diagnostic and self-healing treatment system for a semiconductor device, the system comprising: i) a shunt busting/blocking treatment system, ii) a self-healing treatment system, and iii) an in-situ contact diagnostic system.

In another broad aspect, there is provided herein a method for minimizing non-uniformities and/or defects in a semiconductor device, the semiconductor device having a first electrode layer, a semiconductor layer, and one or more treatment materials to at least a top surface of the semiconductor layer, the treatment material comprising positively and negatively charged particles. The method includes: (i) shunt busting/blocking by applying a reverse bias to the semiconductor device; and/or (ii) self-healing by applying an external forward bias to the semiconductor device; and/or, optionally self-healing by applying external energy to the semiconductor device; and optionally, iii) conducting a non-contact diagnostic evaluation of the semiconductor device by providing a displacement current at a given frequency through the semiconductor device.

In certain embodiments, the method includes providing sufficient reverse bias power through the semiconductor device to drive a reverse current through any shunts present in the semiconductor device, and/or cause a substantial blocking and/or evaporation of the shunts.

In certain embodiments, the method includes providing sufficient forward bias power through the semiconductor device to substantially block low voltage regions in the semiconductor device.

In certain embodiments, the in-situ evaluation provides characterization of the self-healing and/or shunt busting treatments and an indication of whether the self-healing and/or shunt busting treatments provided desired results to the semiconductor device.

In certain embodiments, one or more suitable treatment materials are configured to undergo a chemical and/or physical transformation.

In certain embodiments, the diagnostic evaluation comprises assessment of local surface photovoltage and system local resistance through displacement currents.

In certain embodiments, the frequency is tuned by either a modulated light frequency of the light source or an external AC current source, or both.

In certain embodiments, the treatment material is configured to act as an insulator at high frequencies, is electrically transparent to any displacement currents, and to develop electric currents at lower frequencies.

In certain embodiments, the treatment material comprises one or more materials which undergo a voltage driven- or an electric current driven-electrochemical transformation, thereby providing a coating on low voltage spots on the semiconductor layer.

In certain embodiments, the treatment material comprises one or more materials wherein the voltage driven electrochemical transformations include voltage dependent polymerization at the low voltage spots.

In certain embodiments, the treatment material comprises one or more materials wherein the voltage driven electrochemical transformations include voltage dependent etching or oxidation, or other current blocking layer formation of the low voltage spots.

In certain embodiments, the treatment material comprises one or more aniline materials.

In certain embodiments, the treatment material comprises one or more materials wherein the treatment material includes a combination of one or more aniline materials, p-toluenesulphonic acid, and one or more salts in a deionized water base.

In certain embodiments, the treatment material comprises one or more materials wherein the treatment material includes a combination of self-assembling polyelectrolytes and perylene diimide.

In certain embodiments, the treatment material comprises one or more materials wherein the treatment material includes an electrolyte suspension of charged particles.

In certain embodiments, the treatment material comprises one or more materials wherein the treatment material includes an electrolyte suspension of dipole particles

In certain embodiments, the semiconductor device comprises one or more semiconductor devices that are used to generate voltage in response to absorbed light energy, or generate a laterally non-uniform transversal electric current in response to an applied voltage.

In certain embodiments, the semiconductor comprises one or more of: light emitting diode arrays; liquid crystal display drivers; thin-film transistor and diode drivers underlying large-area displays; sensor arrays; X-ray detectors and image sensors; non-photo-active devices where nonuniformities are be passivated in response to the electric bias and its developed nonuniform currents; and photovoltaic devices.

In certain embodiments, the sensor arrays comprise sensor arrays integrated with flexible substrates.

In certain embodiments, the treatment material has sufficient conductivity to cause a redistribution of positive and negative charges in the treatment material.

In certain embodiments, wherein the conductivity is within the range of from about 0.1 to about 1000 S/m.

In certain embodiments, the external energy is light energy in the visible and/or UV spectrum.

In certain embodiments, the intensity and spectrum of the light energy is sufficient to be absorbed into the semiconductor layer of the device and to cause a redistribution of positive and negative charges in the treatment material.

In certain embodiments, the intensity of the light energy is within the range of from about 0.1 to about 5.0 sun.

In another broad aspect, there is provided herein a diagnostic and self-healing treatment system for a semiconductor device having a substrate layer, a base electrode layer, a semiconductor layer, and at least one electrochemically active treatment material applied to at least a top surface of the semiconductor layer. The system generally includes: at least a first conductive electrode lead configured to be removably connected to the base electrode layer; at least a second conductive electrode lead configured to be removably connected to the electrochemically active treatment material; at least a first external power source configured to be removably connected to the first conductive electrode lead and the second conductive electrode lead; and at least one device configured to conduct a non-contact diagnostic evaluation of the semiconductor device based on impedance measurements; and optionally at least a second external power source configured to be removably connected to the first conductive electrode lead and the second conductive electrode lead.

In certain embodiments, the first external power source is configured to supply a forward external bias to the system.

In certain embodiments, the first external power source is configured to provide a forward external bias to the semiconductor layer of the semiconductor device substantially sufficient to cause a redistribution of positive and negative charges in the electrochemically active treatment material.

In certain embodiments, an energy source is configured to provide energy to at least a top surface of the electrochemically active treatment material.

In certain embodiments, the energy source comprises a source of light energy.

In certain embodiments, the energy source is configured to supply a forward external bias applied to the system.

In certain embodiments, the light energy comprises visible and/or UV spectra.

In certain embodiments, the light energy is supplied by one or more of the sun, a laser, or a tungsten-halogen lamp light.

In certain embodiments, the energy source is configured to provide an intensity and spectrum of light energy substantially sufficient to be absorbed into the semiconductor layer of the semiconductor device and to cause a redistribution of positive and negative charges in the electrochemically active treatment material.

In certain embodiments, the energy source is configured to provide an intensity of the light energy within a range from about 0.1 to about 5.0 sun.

In certain embodiments, the second external power source is configured to supply a reverse external bias to the system.

In certain embodiments, the second power source is configured to drive a reverse current through any shunts or defects in the semiconductor layer 16 substantially sufficient to substantially cause evaporation of the shunts or defects.

In certain embodiments, the non-contact diagnostic device comprises an impedance meter configured to provide information about local surface photovoltage and system local resistance through displacement currents provided by the impedance meter at a given frequency.

In certain embodiments, a frequency modulator is configured to be capable of tuning the frequency of the external energy source and/or tuning the frequency of an external AC current source.

In certain embodiments, a frequency modulator is configured to be capable of tuning the frequency of the light source.

In certain embodiments, the semiconductor device further includes one or more of a transparent electrode and a protective layer at least adjacent to the electrochemically active treatment material.

In certain embodiments, at least a first switch is operatively connected to the first power source and at least a second switch is operatively connected to the second power source. The first and second switches can be configured to allow for reverse and forward bias treatment to the semiconductor device.

In certain embodiments, at least a third switch is operatively connected to the external AC current source and is configured to provide frequency dependent impedance measurements.

Various objects and advantages of this invention will become apparent to those skilled in the art from the following detailed description of the preferred embodiment, when read in light of the accompanying drawings.

### BRIEF DESCRIPTION OF THE DRAWING

FIG. 1 is a schematic illustration of a self-healing universal non-uniformity treatment (SHUNT) system.

### DETAILED DESCRIPTION OF THE PREFERRED EMBODIMENT

In a broad aspect, there is provided herein an improved system for treating structural nonuniformities in semiconductor devices. The system described herein modifies the electric potential of localized defect areas within the semiconductor device to create a more uniform distribution of the electric potential generated by the semiconductor device.

In another aspect, there is provided herein a system of making a semiconductor device that provides an improvement over the method that was developed by the inventors herein for healing of non-uniformities in semiconductor devices that is described in the Karpov et al. U.S. Pat. No. 7,098,058, which is fully incorporated herein by reference.

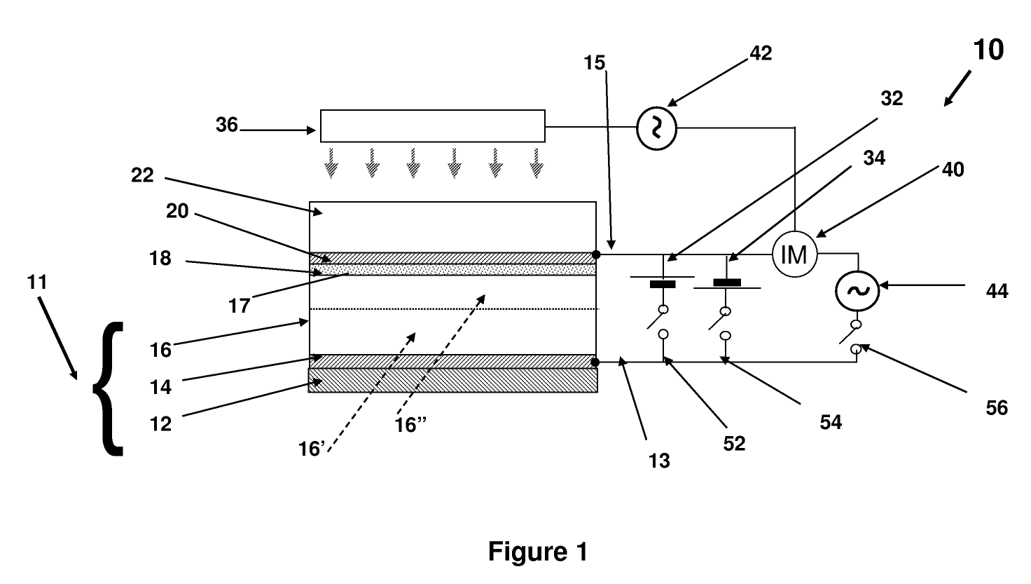

Referring now to the drawings, there is shown in FIG. 1 a self-healing universal non-uniformity treatment (SHUNT) system 10 that combines a self-healing treatment with a shunt busting treatment and an in-situ nonuniformity diagnostic function. FIG. 1 is a generalized schematic illustration of a semiconductor device 11 that may be manufactured according to the method of the present invention. The illustrated configuration for the semiconductor device 11 is intended merely to illustrate examples of semiconductor cell configurations in which this invention may be used.

It will also be appreciated that the SHUNT system 10 described herein may be used in the manufacture of any semiconductor device. Non-limiting examples include semiconductor devices that are used to generate voltage in response to absorbed light energy, or generate a laterally non-uniform transversal electric current in response to the applied voltage, such as light emitting diode arrays or liquid crystal display drivers.

Other non-limiting examples include thin-film transistor and diode drivers underlying large-area displays, sensor arrays, including those integrated with giant-area flexible substrates, X-ray detectors and image sensors.

It is to be understood that the semiconductor devices that can be diagnosed and/or treated with the SHUNT system 10 as generally described herein do not have to be photo-active and that their nonuniformities will be passivated in response to the electric bias and its developed nonuniform currents, as further explained herein.

Thus, the scope of this invention is not intended to be limited to either photovoltaic cells in general or to the specific structures for the semiconductor device 11 illustrated in FIG. 1

For ease of illustration, FIG. 1 generally shows the semiconductor device 11 as including a substrate layer 12, a base electrode layer 14 and a semiconductor layer 16.

In certain embodiments, the substrate layer 12 is a transparent material, such as glass, but it will be appreciated that other transparent materials can also be used. It will also be appreciated that an opaque substrate material, such as metal, may also be used.

The base electrode layer 14 is applied to the substrate layer 12. The base electrode layer 14 can be composed of either a transparent conductive material, such as a transparent conductive oxide, or a non-transparent conductive material, such as a metallic material. In certain non-limiting embodiments, where a transparent conductive material is used, preferably a transparent conductive oxide material such as a fluorine-doped tin oxide (SnO2:F) is used. It will also be appreciated that any suitable transparent conductive oxide material may also be used. This base electrode layer 14 forms one of the two electric contacts or electrodes for the semiconductor device 11, and is operatively connected to a first conductive electrode lead 13 for conducting current, as further explained below.

The semiconductor layer 16 is applied over the base electrode layer 14. The semiconductor layer 16 is comprised of at least one individual semiconductor layer, which may be configured in any suitable manner. It is to be understood that FIG. 1 generally illustrates the semiconductor layer 16 as a unitary layer for ease of illustration, however, it should be further understood that such semiconductor layer 16 can be comprised of two or more layers.

For example, in certain embodiments, a first layer 16′ can be comprised of a semiconductor material ((for example, cadmium sulfide (CdS)), although it will be appreciated that any suitable semiconductor material may also be used. Another layer 16″ of the semiconductor layer 16 can be comprised of the opposite type semiconductor material. In certain embodiments, this semiconductor material can be p-type cadmium telluride (CdTe), although it will be appreciated that any suitable type semiconductor material may also be used.

In other embodiments, the semiconductor layer 16 can have a multi-junction semiconductor cell which is comprised of a plurality of individual semiconductor cells. In such embodiments, the individual semiconductor cells may be of the single junction, two-layer cell type, a multi-junction semiconductor layer comprised of a plurality of three-layer (often referred to as double junction) cells.

The individual thin-film layers of the semiconductor layer 16 may be applied to the base electrode layer 14 using any suitable application method, such as by vapor transport deposition or electrochemical deposition or by sputtering techniques.

An electrochemically active treatment material 18 is applied to at least a top surface 17 of the semiconductor layer 16. In certain embodiments, at least the top surface 17 can comprise CdTe in CdTe PV or CdS in CIGS PV.

In certain embodiments, the treatment material 18 can be applied in any suitable manner, using for example, a spray or roller application. In other embodiments, the semiconductor layer 16 can be at least partially submerged in the treatment material 18 in order to at least partially block any shunts present in the semiconductor layer 16, as further explained below.

To complete the circuit in the semiconductor device 11, a conductive electrode layer 20 is connected and/or attached to the applied treatment material 18. It is to be understood that, in certain embodiments, the conductive electrode layer 20 can be removably attached to the applied treatment material 18.

The conductive electrode layer 20 serves as the second of the two electric contacts or electrodes for the semiconductor device 11. The conductive electrode layer 20 contains a second conductive lead 15 for conducting current, as explained below.

In certain embodiments, a glass or other protective layer 22 can be applied to the conductive electrode layer 20. Similarly, it is to be understood that the protective layer 22, along with the conductive electrode layer 20, can be removably attached to the applied treatment material 18.

The conductive electrode layer 20 can be composed of either a transparent conductive material, such as a transparent conductive oxide, or a non-transparent conductive material, such as a metallic material. In one non-limiting example, the base electrode layer 14 or the conductive electrode layer 20 of the semiconductor device 11 can be formed from a transparent conductive material, with the remaining electrode layer being formed from a non-transparent material.

Therefore, in certain embodiments, where a transparent conductive material is used for the base electrode layer 14, a non-transparent material is used for the conductive electrode layer 20. Examples of such suitable non-transparent materials for the conductive electrode layer 20 include nickel, titanium, chromium, gold, or aluminum. It will be appreciated, however, that the base electrode layer 14 and the conductive electrode layer 20 may be formed using any suitable materials that allow for light to be absorbed into the semiconductor layer 16 through at least one of the base electrode layer 14 and/or the conductive electrode layer 20. The base electrode layer 14 may be applied to the semiconductor device 11 using any suitable thin-film application method, such as sputtering or evaporation techniques.

Often, in both simple and multi-junction PV cell designs, a number of structural nonuniformities and/or defects are formed during the manufacturing of the semiconductor device 11. These nonuniformities and/or defects can be present throughout the semiconductor layer 16 of the semiconductor device 11. These defects can occur for numerous reasons. For example, such defects as “irregularities” can be caused by the deposition process used to form the various semiconductor layers. Other defects can be caused by morphological irregularities in the deposition surface of the substrate material 12.

These defects throughout the various semiconductor layers 16 generally result in nonuniformities, which cause one or more areas of aberrant electric potential in the top surface 17 of the semiconductor layer 16. These areas of aberrant electric potential (caused by the nonuniformities) deviate from the average electric potential of the remainder of the top surface 17 of the semiconductor layer 16. In addition, these areas of aberrant electric potential can cause a decrease in the performance of the semiconductor device 11.

Other defects that can also occur are generally referred to as “shunt defects.” The “shunt defects” are generally present in semiconductor devices when one or more low resistance current paths develop through the semiconductor body of the device, thereby allowing current to pass unimpeded between the electrodes thereof. As such, under operating conditions, a semiconductor device in which a shunt defect has developed, exhibits either (1) a low power output, since electrical current collected at the electrodes flows through the defect region (the path of least resistance) in preference to an external load, or (2) complete failure where substantially sufficient current is shunted through the defect region to “burn out” the device.

In order to mitigate or eliminate such defects, the treatment material 18 is applied during the manufacturing of the semiconductor device 11. In certain embodiments, the treatment material 18 acts to level out the surface potential variations caused by the nonuniformities in the top surface 17 of the semiconductor layer 16. In certain embodiments, it is desired that the treatment material 18 has substantially sufficient conductivity to cause the redistribution of the positive and negative charges and/or ions of the treatment material 18. The treatment material 18 is generally a conductive material that includes particles that act both as an electrolyte and as a bonding material. In certain embodiments, the particles can range in size from nanoparticle size to micron size. The size of the particles present in the treatment material 18 can be optimized, depending on the type of semiconductor layer 16 to which the treatment material 18 is being applied.

In one particular embodiment, the SHUNT system 10 uses a bias-induced application of energy (via the electrode leads 13 and 15) such that the external bias through the treatment material 18 will substantially force a laterally non-uniform transversal electric current in response to the applied voltage through the semiconductor layer 16.

When either the forward or reverse bias is applied to the semiconductor layer 16, the SHUNT system 10, causes a redistribution of the positive and negative charges of the treatment material. Also, in certain embodiments, the SHUNT system 10 causes the treatment material 10 to bond to the top surface of the semiconductor layer 18.

In certain embodiments, the conductivity of the treatment material 18 can be within the range of from about 0.1 to about 1000 S/m.

In certain embodiments, it is desired that the treatment material 18 is capable of providing a voltage driven electrochemical transformation, which then leads to a preferential coating of low voltage spots on the underlying semiconductor layer 16.

Also, the treatment material 18 is capable of providing an electric current driven electrochemical transformation, which then leads to preferential coating of low voltage spots on the underlying semiconductor layer 16.

The voltage driven electrochemical transformations can include voltage dependent polymerization at the low voltage spots. In addition, the voltage driven electrochemical transformations can include voltage dependent etching or oxidation, or other current blocking layer formation of the low voltage spots.

Also, in certain embodiments, the treatment material 18 provides a self-healing treatment that is aided by the presence of one or more types of suspension particles in the treatment materials 18. The suspension particles of the treatment material 18 are deposited in a non-uniform fashion on the semiconductor layer 16, thereby concentrating on “weak” spots that run high local currents and minimizing the weak spots.

The suspension particles in the treatment material 18 can physically fill (i.e., clog or block), the shunts that are present in the semiconductor layer 16, thereby providing a shunt “blocking” treatment to the semiconductor layer 16. Also, the suspension particles in the treatment material 18 can chemically react with the semiconductor layer 16 to heal the defects in the semiconductor layer 16.

In one non-limiting example, a suitable treatment material 18 can include one or more aniline materials. In certain other non-limiting embodiments, the treatment material 18 can include a combination of one or more aniline materials, p-toluenesulphonic acid, and one or more salts (such as NaCl) in a deionized water base.

In other non-limiting embodiments, the treatment material 18 can include a combination of self-assembling polyelectrolytes and perylene diimide.

In still other non-limiting embodiments, the treatment material 18 can include an electrolyte (water) suspension of charged and/or dipole particles, such as red wine or similar suspensions.

It is to be understood that especially useful treatment materials 18 generally behave as an insulator at high frequencies and are electrically transparent to the displacement currents, while also being capable of developing real electric current at lower frequencies.

Referring again to FIG. 1, the self-healing universal non-uniformity treatment (SHUNT) system 10 includes at least one external power source 32, and in certain embodiments, at least a second power source 34, that is connected to the first and second conductive electrode leads 13 and 15, respectively. Also, in certain embodiments, the SHUNT system 10 can include an external energy source 36, as further explained herein. It is to be understood that the term “external” generally refers to the source not being a part of the semiconductor device 11.

In certain embodiments, an external bias applied by the SHUNT system 10 can be a forward bias. The forward bias can be supplied by the external power source 32 and/or by the external light 36. In certain embodiments, the energy source 36 can be any suitable light energy that can be absorbed by the semiconductor layer 16 that is being diagnosed and/or treated. The light energy can be in visible and/or UV spectra and can be supplied by the sun, laser, a tungsten-halogen lamp light or other suitable light energy sources.

In non-limiting certain embodiments, the intensity of the light energy can be, for example, within the range of from about 0.1 to about 5.0 sun.

In certain embodiments, the intensity and spectrum of the light energy alone is substantially sufficient to be absorbed into the semiconductor layer 16 of the semiconductor device 11 and to cause the redistribution of the positive and negative charges in the treatment material 18.

In other non-limiting examples, both the applied external electric bias and/or the intensity and spectrum of the light energy are substantially sufficient to be absorbed into the semiconductor layer 16 of the semiconductor device 11 and to cause a redistribution of the positive and negative charges within the treatment material 18.

In still other non-limiting embodiments, the SHUNT system 10 is operated without the application of any external energy from the energy source 36 to the semiconductor layer 16. For example, the SHUNT system 10 can be configured to provide a reverse bias, such as supplied by the second power source 34, applied to the semiconductor device 11. The reverse bias power thus drives extremely high reverse currents through any shunts and/or defects in the semiconductor layer 16, thereby leading to their evaporation (i.e., shunt busting).

The SHUNT system 10 can also provide a method for conducting a non-contact diagnostic evaluation of the semiconductor device 11. In general, the diagnostic evaluation is based on impedance measurements. In the embodiment shown in FIG. 1, the SHUNT system 10 further includes a measuring device 40, such as an impedance meter (IM), to measure the impedance through the semiconductor device 11. By using the impedance meter 40, the SHUNT system 10 provides information about local surface photovoltage (SPV) and the system local resistance through displacement currents provided by the impedance meter 40 at a given frequency. The light intensity from the energy source 36 can be modulated, generating the correspondingly modulated SPV that is read by the impedance meter 40 through a lock-in amplifier technique.

In certain embodiments, the frequency can be tuned by a light frequency modulator 42 operatively connected to the light source 36. Also, the frequency can be tuned by being operatively connected to an external AC current source 44.

In the embodiment illustrated in FIG. 1, the energy (generally shown as arrows) is supplied from the energy source 36 to the treatment material 18 by passing through the transparent electrode 20 and the protective layer 22. However, it is to be noted that in certain embodiments, the energy can be directly supplied to the treatment material 18 before the electrode 20 and/or the protective layer 22 are applied to the semiconductor device 11.

In certain embodiments, the SHUNT system 10 further includes first and second switches 52 and 54, respectively, that are operatively connected to the first and second power sources 32 and 34, respectively, to allow for both a reverse bias treatment and a forward bias treatment. In addition, the SHUNT system 10 can include a third switch 56 operatively connected to the external AC current source 44 in order to provide the added functionality of the frequency dependent impedance measurements.

The SHUNT system 10 described herein provides a self-healing treatment system that is combined with a shunt busting treatment, and with an in-situ non-uniformity diagnostic system. Use of the SHUNT system 10 substantially heals or minimizes any non-uniformity loss components in the semiconductor device 11 that may be due to weak SPV spots, known as weak micro-diodes, and any “true” ohmic shunts, such as metal protrusions. Use of the SHUNT system 10 also provides an in-situ diagnostic evaluation of the “self-healing” and/or “shunt busting” treatments and whether such treatments provided the desired healing results. The diagnostic evaluation provides an “in situ” evaluation since the evaluation can be performed during the manufacturing of the semiconductor device 11.

The SHUNT system 10 is especially useful where any weak diode spots are present since the weak diode spots are blocked by the application of a suitable treatment material 18. That is, the treatment material 18 can undergo a chemical and/or physical transformation at those weak diode spots. These transformations are generally related to any significant local variations in the electric current density when the semiconductor device 11 is under an external bias.

In another aspect, there is provided a method for (1) diagnosing non-uniformities and (2) minimizing defects in the semiconductor device 11. In particular, the method is useful to minimize defects by (a) shunt busting by applying a reverse bias, (b) self-healing by applying an external forward bias, and/or (c), self-healing by applying a light treatment.

The SHUNT system 10 is useful to reduce the non-uniformity loss in all kinds of semiconductor devices; and in certain embodiments, increasing the generated power by up to 30% or more. Thus, the SHUNT system 10 is useful in the manufacturing of multiple types of film compositions having differing morphologies.

In the SHUNT system 10, the electro-chemical treatment is less toxic and provides a higher degree of manufacturing flexibility than earlier methods for reducing non-uniformities.

Among the advantages of the SHUNT system 10 described herein are that the SHUNT system 10: 1) applies self-healing treatments to block low surface photovoltage (SPV) spots in various types of semiconductor devices under external bias and/or light; 2) combines self-healing treatments with shunt busting and/or blocking capability; 3) provides in-situ, capacitive diagnostics of non-uniformity loss before and after treatment applications; 4) provides a universal diagnostic and/treatment system that substantially alleviates the above discussed problems for multiple types of semiconductor technologies; and 5) provides a universal diagnostic and/treatment system which is readily scaled up for use in commercial applications.

Still other advantages of the SHUNT system 10 include the capability for i) passivation of low voltage spots in CdTe and other PV devices; ii) shunt passivation and busting; iii) in situ diagnostics of low voltage and shunt related loss.

In addition, the SHUNT system 10 allows the use of different types of treatment materials, including both organic and inorganic materials that are capable of being tunable in a broad range of factors.

Further, the SHUNT system 10 provides application procedures that are adaptable to specific manufacturing processes. The steps can include treatment: 1) under external forward bias, and/or 2) under external reverse bias, and/or 3) with or without any concomitant supply of external energy (e.g., illumination), while simultaneously being “tunable” or adjustable to the specific semiconductor device being treated and/or evaluated.

Still further, the SHUNT system 10 provides the advantages of: 1) a much broader choice of treatments by being capable of responding either to voltage or light; 2) not necessarily limited to use of organic treatment materials; but provides for the ability to use high temperature tolerant inorganic treatments; 3) much shorter treatment times which are allowed by the “dark” condition treatments under external bias, rather than merely a “light” treatment; and 4) in-situ diagnostics which allow for the tweaking or adjusting of the treatment during its application and for the flexibly of tuning or adjusting the treatment to meet specific desired device parameters.

Thus, the SHUNT system 10 enables a semiconductor manufacturer to conduct any necessary self-healing and/or shunt treatments without the need for light exposure to the semiconductor device, thereby protecting against detrimental heating and/or consequent glass breakage of the protective layer 20.

The advantage of the SHUNT system 10 being “tunable” allows the SHUNT system 10 to be useful with a variety of types of semiconductor structures. In one embodiment, for example, using optically transparent electrodes (such as TCO on glass) facilitates the combination of photo- and bias-induced effects. In addition, the bias induced treatments can be readily combined with the functionalities of both shunt busting and capacitive current diagnostics of non-uniformity effects.

In addition, the SHUNT system 10 provides the manufacturer with the ability to reduce any non-uniformity power loss in the semiconductor device 11. The SHUNT system 10 also allows the manufacturer to conduct diagnostic functions, not only of any original non-uniformity that may be initially present, but also to determine whether the self-healing and/or shunt busting treatments were useful to achieve the desired results. In certain embodiments, if the diagnostic function indicates that there are still undesired defects, further self-healing and/or shunt busting treatments can be supplied by the SHUNT system 10 to semiconductor device 11.

In one particular diagnostic application, the SHUNT system 10 can be configured to provide a modulated light and/or voltage which creates alternating currents across an insulating gap that is provided by the treatment material 18. In effect, the SHUNT system 10 provides a capacitance circuit through the semiconductor device 11.

The diagnostic application can be also used to preliminarily assess the semiconductor device 11 before any healing treatments (self-healing and/or shunt busting/blocking) are applied. In such preliminary diagnostic application, current can be sent through the semiconductor device 11 to detect any current leakage, thereby allowing the manufacturer to determine whether any treatment, or how much treatment, is needed. That is, by modulating the voltage, with no contact application, the SHUNT system 10 allows the treatment material 18 to act as the insulating gap.

In yet another aspect, the SHUNT system 10 can be used with any suitable software, in conjunction with the capacitive diagnostic capabilities of the SHUNT process, in order to facilitate the analysis of the diagnostic results.

The foregoing has outlined in broad terms the more important features of the invention disclosed herein so that the detailed description that follows may be more clearly understood, and so that the contribution of the instant inventor to the art may be better appreciated. The instant invention is not to be limited in its appreciation to the details of the construction and to the arrangements of the components set forth in the description herein or illustrated in the drawings herein. Rather, the invention is capable of other embodiments and of being practiced and carried out in various other ways not specifically enumerated herein.

It should be understood that the phraseology and terminology employed herein are for the purpose of description and should not be regarded as limiting, unless the specification specifically so limits the invention.

Also, while the invention has been described with reference to various and preferred embodiments, it should be understood by those skilled in the art that various changes may be made and equivalents may be substituted for elements thereof without departing from the essential scope of the invention. In addition, many modifications may be made to adapt a particular situation or material to the teachings of the invention without departing from the essential scope thereof. Therefore, it is intended that the invention not be limited to the particular embodiment disclosed herein contemplated for carrying out this invention, but that the invention will include all embodiments falling within the scope of the claims.

What is claimed is:

1. A diagnostic and self-healing treatment system for a semiconductor device, the system comprising: i) a shunt busting/blocking treatment system, ii) a self-healing treatment system, and iii) an in-situ contact diagnostic system.

2. A method for minimizing non-uniformities and/or defects in a semiconductor device, the semiconductor device having a first electrode layer, a semiconductor layer, and one or more treatment materials to at least a top surface of the semiconductor layer, the treatment material comprising positively and negatively charged particles; the method comprising:
(i) shunt busting/blocking by applying a reverse bias to the semiconductor device; and/or
(ii) self-healing by applying an external forward bias to the semiconductor device; and/or, optionally self-healing by applying external energy to the semiconductor device; and optionally,
iii) conducting a non-contact diagnostic evaluation of the semiconductor device by providing a displacement current at a given frequency through the semiconductor device.

3. The method of claim 2, including providing a substantially sufficient reverse bias power through the semiconductor device to drive a reverse current through any shunts present in the semiconductor device, and/or cause a substantial blocking and/or evaporation of the shunts.

4. The method of claim 2, including providing substantially sufficient forward bias power through the semiconductor device to substantially block low voltage regions in the semiconductor device.

5. The method of claim 2, wherein the in-situ evaluation provides characterization of the self-healing and/or shunt busting treatments and an indication of whether the self-healing and/or shunt busting treatments provided desired results to the semiconductor device.

6. The method of claim 2, wherein one or more suitable treatment materials are configured to undergo a chemical and/or physical transformation.

7. The method of claim 2, wherein the diagnostic evaluation comprises assessment of local surface photovoltage and system local resistance through displacement currents.

8. The method of claim 2, wherein the frequency is tuned by either a modulated light frequency of the light source or an external AC current source, or both.

9. The method of claim 2, wherein the treatment material is configured to act as an insulator at high frequencies, is electrically transparent to any displacement currents, and to develop electric currents at lower frequencies.

10. The method of claim 2, wherein the treatment material comprises one or more materials which undergo a voltage driven- or an electric current driven-electrochemical transformation, thereby providing a coating on low voltage spots on the semiconductor layer.

11. The method of claim 10, wherein the treatment material comprises one or more materials wherein the voltage driven electrochemical transformations include voltage dependent polymerization at the low voltage spots.

12. The method of claim 10, wherein the treatment material comprises one or more materials wherein the voltage driven electrochemical transformations include voltage dependent etching or oxidation, or other current blocking layer formation of the low voltage spots.

13. The method of claim 2, wherein the treatment material comprises one or more aniline materials.

14. The method of claim 2, wherein the treatment material comprises one or more materials wherein the treatment material includes a combination of one or more aniline materials, p-toluenesulphonic acid, and one or more salts in a deionized water base.

15. The method of claim 2, wherein the treatment material comprises one or more materials wherein the treatment material includes a combination of self-assembling polyelectrolytes and perylene diimide.

16. The method of claim 2, wherein the treatment material comprises one or more materials wherein the treatment material includes an electrolyte suspension of charged and/or dipole particles.

17. The method of claim 2, wherein the semiconductor device comprises one or more semiconductor devices that are used to generate voltage in response to absorbed light energy, or generate a laterally non-uniform transversal electric current in response to an applied voltage.

18. The method of claim 2, wherein the semiconductor comprises one or more of: light emitting diode arrays; liquid crystal display drivers; thin-film transistor and diode drivers underlying large-area displays; sensor arrays; X-ray detectors and image sensors; non-photo-active devices where nonuniformities are to be passivated in response to the electric bias and its developed nonuniform currents; and photovoltaic devices.

19. The method of claim 18, wherein the sensor arrays comprises sensor arrays integrated with flexible substrates.

20. The method of claim 2, wherein the treatment material has substantially sufficient conductivity to cause a redistribution of positive and negative charges in the treatment material.

21. The method of claim 20, wherein the conductivity is within the range of from about 0.1 to about 1000 S/m.

22. The method of claim 2, in which the external energy is light energy in the visible and/or UV spectrum.

23. The method of claim 22, wherein the intensity and spectrum of the light energy is substantially sufficient to be absorbed into the semiconductor layer of the device and to cause a redistribution of positive and negative charges in the treatment material.

24. The method of claim 23, wherein the intensity of the light energy is within the range of from about 0.1 to about 5.0 sun.

25. A diagnostic and self-healing treatment system for a semiconductor device (11) having a substrate layer (12), a base electrode layer (14), a semiconductor layer (16), and at least one electrochemically active treatment material (18) applied to at least a top surface (17) of the semiconductor layer (16), the system comprising:
at least a first conductive electrode lead (13) configured to be removably connected to the base electrode layer (14);
at least a second conductive electrode lead (15) configured to be removably connected to the electrochemically active treatment material (18);
at least a first external power source (32) configured to be removably connected to the first conductive electrode lead (13) and the second conductive electrode lead (15); and
at least one device (40) configured to conduct a non-contact diagnostic evaluation of the semiconductor device (11) based on impedance measurements; and optionally
at least a second external power source (34) configured to be removably connected to the first conductive electrode lead (13) and the second conductive electrode lead (15).

26. The system of claim 25, wherein the first external power source (32) is configured to supply a forward external bias to the system 10.

27. The system of claim 25, wherein the first external power source (32) is configured to provide a forward external bias to the semiconductor layer (16) of the semiconductor device (11) substantially sufficient to cause a redistribution of positive and negative charges in the electrochemically active treatment material (18).

28. The system of claim 25, further including an energy source (36) configured to provide energy to at least a top surface of the electrochemically active treatment material (18).

29. The system of claim 28, wherein the energy source (36) comprises a source of light energy.

30. The system of claim 28, wherein the energy source (36) is configured to supply a forward external bias applied to the system 10.

31. The system of claim 29, wherein the light energy comprises visible and/or UV spectra.

32. The system of claim 29, wherein the light energy is supplied by one or more of the sun, a laser, or a tungsten-halogen lamp light.

33. The system of claim 29, wherein the energy source (36) is configured to provide an intensity and spectrum of light energy substantially sufficient to be absorbed into the semiconductor layer (16) of the semiconductor device (11) and to cause a redistribution of positive and negative charges in the electrochemically active treatment material (18).

34. The system of claim 29, wherein the energy source (36) is configured to provide an intensity of the light energy within a range from about 0.1 to about 5.0 sun.

35. The system of claim 25, wherein the second external power source (34) is configured to supply a reverse external bias to the system 10.

36. The system of claim 25, wherein the second power source (34) is configured to drive a reverse current through any shunts or defects in the semiconductor layer 16 substantially sufficient to substantially cause evaporation of the shunts or defects.

37. The system of claim 25, wherein the non-contact diagnostic device (40) comprises an impedance meter configured to provide information about local surface photovoltage and system local resistance through displacement currents provided by the impedance meter (40) at a given frequency.

38. The system of claim 37, further including a frequency modulator (42) configured to be capable of tuning the frequency the external energy source (36) and/or tuning the frequency of an external AC current source (44).

39. The system of claim 37, further including a frequency modulator (42) configured to be capable of tuning the frequency of the light source (36).

40. The system of claim 25, wherein the semiconductor device (11) further includes one or more of a transparent electrode (20) and a protective layer (22) at least adjacent to the electrochemically active treatment material (18).

41. The system of claim 25, further including at least a first switch (52) operatively connected to the first power source (32) and at least a second switch (54) operatively connected to the second power source (34), the first and second switches being configured to allow for reverse and forward bias treatment to the semiconductor device (11).

42. The system of claim 38, further including at least a third switch (56) operatively connected to the external AC current source (44) and configured to provide frequency dependent impedance measurements.
